(19) United States
(12) Patent Application Publication
(10) Pub. No.: US 2010/0215840 A1
(43) Pub. Date: Aug. 26, 2010

(54) METHOD AND COMPOSITION TO ENHANCE CORROSION RESISTANCE OF THROUGH HOLE COPPER PLATED PWBs FINISHED WITH AN IMMERSION METAL COATING SUCH AS Ag OR Sn

(75) Inventor: John J. Grunwald, Ramat Gan (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: J.G. Systems Inc., Miami, FL (US)

(21) Appl. No.: 12/769,675

(22) Filed: Apr. 29, 2010

(30) Foreign Application Priority Data
Mar. 11, 2010 (IL) 204422

(51) Int. Cl. H05K 3/46

(52) U.S. Cl. 427/96.2

(57) ABSTRACT

This invention teaches deposition of a corrosion-barrier layer onto a copper substrate, which minimizes copper corrosion even if the final immersion top layer is not without pinholes. Such barrier layer can comprise a copper conversion coating, corrosion resistant immersion deposited metal coatings such as palladium, gold, etc. The deposition of a barrier layer is generally followed by immersion deposition of a metal plate such as for example silver, tin, or others, designed to promote solderability.

The patent also envisions the barrier layer as a “stand alone” final finish, serving both as a corrosion barrier layer and at the same time will promote solderability.

The patent further teaches ways to minimize the problems of black nickel formation in the field, when the final finish is an electroless Ni—P (EN), topped with immersion gold.

The object of this patent is to eliminate, or at least significantly reduce corrosion problems associated with immersion deposited metal coatings used as final finish for through hole copper plated Printed Wiring Boards (PWBs), even in the presence of microvoids or pinholes contained in the top layer of immersion deposited metal film.

The inventor of this patent, has recently filed an application published as US2010040773. Above application referenced herewith in its entirety, teaches methods and compositions designed to cap pinholes and micro voids with electrolessly plated metal, thereby avoiding or minimizing galvanic corrosion of the copper metal substrate.

Such microvoids are unavoidably present in displacement deposits, and leave exposed/unprotected copper areas that corrode when subjected to polluted environments. The exposed copper will form a galvanic cell, with the immersion deposited metal acting as cathode and the exposed copper acting as anode. The outcome is creep corrosion, leading to failure in the field of costly PWBs.

Instant patent teaches ways to minimize corrosion of immersion metal coated PWBs, in cases where capping pinholes with metal may not be practicable, for whatever reason. It thus offers an alternative to capping, and will reduce copper corrosion even in presence of unavoidable pinholes in the immersion metal film used as final finish.

### PRIOR ART

This application will rely on the extensive discussion of the prior art that has been presented in above referenced pending U.S. application. It will not be dealt with here, as it would be redundant.

### BRIEF DESCRIPTION OF THE INVENTION

The object of this invention is to eliminate or at least minimize copper corrosion, even in the presence of the pinholed immersion deposited top metal layer. This is achieved by depositing/interposing a corrosion-barrier layer onto the copper substrate, and prior to immersion deposition of a metal film, such as silver or tin.

Indeed, such coatings immediately adjacent to the surface of the copper metal will act as barriers to corrosion, as will be detailed further.

The barrier layer may comprise a copper conversion coating, a corrosion resistant immersion-deposited metal layer such as palladium, gold, and the like.

It is to be noted that for the purpose of simplification and in the broad context of this patent, the term conversion coating or barrier coatings, will encompass immersion metal deposits as well, as long as they precede the top, outer surface of the finished printed circuit board.

While not bound by the mechanism surmised below, it is hypothesized that the unexpected beneficial result of the barrier layer, is due to one of the following:

1. The barrier layer alters the capillarity of the pinholes, making the underlying copper metal less accessible to the corrosive vapors, and/or restricting the migration of the copper corrosion product to the outer surface of PWBs.

2. The barrier layer accelerates nucleation of the immersion deposited metal that follows, by acting as in-situ cathode instantly, as the copper substrate is contacted with metal immersion solution, perhaps thereby reducing the number of pinholes, and also possibly making the pinhole diameter smaller.

3. The barrier layer decreases electrical surface conductivity of the copper surface, resulting in reduced current flow between galvanic cells, thereby slowing anodic copper corrosion.

4. The barrier layer decreases the electric potential of the galvanic cell, reducing the driving force for corrosion.

In the context of this patent, the term conversion coating denotes a coating obtained when the surface of a clean metal substrate such as copper, is contacted with a liquid, vapor or gas, that react with copper metal surface, to yield a coating or film of a copper reaction product that forms a chemical bond with the copper substrate. In the prior art, such coatings or films are generated for functional benefits, mainly corrosion protection.

Also, in the context of this patent, the term barrier coating denotes a coating formed on the copper metal surface as described in the previous paragraph, that will act as barrier to copper corrosion, when the PWB with its final finish, is exposed to corrosive environment.

The prior art failed to recognize the usefulness of a conversion coating prior to immersion deposition of a displacement type metal plate, and thus failed to recognize that said conversion coating can act as a barrier to corrosion.

Specifically, there is no mention in the prior art that conversion coatings can assist in reducing corrosion, and particularly creep corrosion of immersion deposited metal films, such silver, tin, etc., over copper.

Also, while deposits of palladium or palladium derivatives are widely practiced as catalysts or activators to initiate or trigger electroless deposition of autocatalytic metals on non-metallic substrates or non-catalytic metal substrates such as copper, their usefulness and potential benefits prior to displacement type metal deposition processes has been missed, as it would seem unjustified and seemingly superfluous.

Indeed, immersion metal deposition is self-starting and takes place as a result of the dissolving substrate releasing electrons, which electrons then reduce the metallic ions to metal. There is therefore no rational expectation that a palladium layer will be beneficial prior to immersion deposition of displacement type coatings.

The two dominant displacement type immersion deposits principally used to promote solderability and corrosion protection of PCBs, are tin and silver. Stannous tin is known to poison the catalytic action of palladium, and would seemingly be counterproductive. Also, silver ions are believed to be marginally autocatalytic, if at all, again suggesting the uselessness of a Pd film prior to immersion silver.

Therefore, to envision palladium as a beneficial base for the deposition of immersion metal deposits such as tin or immersion silver, goes against the teachings of the prior art, which prior art in fact teaches away from this invention.

### DETAILED DESCRIPTION OF THE INVENTION

It is the object of this invention to reduce corrosion of copper through hole plated PWBs that use immersion-deposited metal for corrosion protection and solderability, even though they may contain microvoids and pinholes.

It was discovered in this invention, that by depositing a film of palladium metal, or by forming copper a conversion coating as corrosion barriers onto the copper substrate and prior to immersion or displacement metal deposition, one obtains the following unexpected advantages:

1. The Pd barrier film greatly accelerates the initiation of the immersion metal deposition process.

2. It allows to operate the immersion plating processes at solution temperatures well below accepted practice.

Again, and at the risk of being redundant, the mechanism of above cited benefits is not well understood, and can only be speculated as follows:

1. The palladium or conversion film acts cathodically and accelerates the kinetics of the nucleation reaction that releases electrons, which in turn reduce the metal ions to metal, that result in the immersion or displacement deposit.

2. The palladium film liberates hydrogen, which perhaps acts as auxiliary reducer, along with the electrons released by the dissolving metal substrate, which in the case of PCBs, is copper.

3. The palladium film minimizes the “population” of pinholes and/or alters/reduces their size because of accelerated initial metal nucleation.

4. The palladium film interferes with the diffusion of corroding vapors to the copper substrate, and also bars the diffusion of copper corrosion producs to the outer surface of the copper substrate, thereby slowing the corrosion process.

5. The immersion deposited barrier Pd film covers the copper substrate with a greatly reduced pihole surface “density” as compared to pinhole surface “density” of immersion metals such such as Ag, when deposited directly over copper. This would mean that Ag is essentially capping the Pd film via greatly reduced areas of exposed copper pores, sufficient though to act anodically for the reduction of Ag ions to silver metal.

The palladium film thus acts as a bottleneck for the mass transfer of corrosive vapors towards the substrate, and transfer of corrosion salts away from the substrate, thereby delaying or avoiding the onset of creep corrosion.

Part, if not all, of the above speculated reasons and mechanisms that try to explain the unexpected benefits of a Pd barrier layer over copper, are also applicable to the benefits derived from using copper conversion films as barriers.

In a preferred embodiment of this invention, a copper conversion layer is formed on the copper substrate prior to immersion deposition of the desired displacement metal plated layer, such as principally silver and tin.

The copper conversion coating can be a copper oxide, phosphate, borate, copper imidazole, copper benzotriazole, copper molybdate, tungstate, and others.

It is a preferred embodiment of this invention to form the conversion coating over copper in the same solution that is designed to provide the copper substrate with a microetched topography, routinely practiced prior to immersion metal deposition. Such microetch solutions are generally based on acidic hydrogen peroxide, persulphate, or cupric copper compositions, and they can conveniently comprise the conversion film-forming compound selected from the group of MBT, imidazole, triazole, etc.

A worker skilled in the art can choose a suitable conversion composition and process from an abundance of published information, as such conversion coatings are widely practiced in metal finishing industry, especially for the corrosion protection of electrolytic zinc.

In selecting a suitable conversion type barrier layer, the following proposed criteria are to be kept in mind:

1. It should promote corrosion protection of the immersion metal plated, pinholed copper substrate when it is exposed to corrosive fumes.

2. It should not block or impede the immersion metal deposition reaction that follows it.

3. It should be friendly to the environment, and safe to use.

This last criterion can be illustrated and exemplified by the chromate-free conversion coatings on electroplated zinc, that avoid use of environmentally objectionable, and dangerous chromic acid or chromic acid derivatives.

Again, the embodiment of a copper conversion coating seeks to avoid immersion metal deposition directly on “pure”, electrically conductive copper metal, as favored by the prior art. Instead, immersion metal deposition is formed adjacently to, and/or on top of the intermediate copper conversion layer.

Again, above embodiment goes counter the well known prior art's accepted best practice that endeavors to ensure, “pink” copper surface as preferred foundation for immersion metal deposition.

As mentioned earlier, the immersion metal plated deposit such as silver, is separated from the copper substrate by a corrosion resistant barrier layer of palladium, gold, and others.

The palladium barrier layer in this invention will be of sufficient thickness to alter the “pink” copper color of the substrate. The same observation is applicable for the copper conversion film.

The person skilled in the prior art will need to optimize the thickness of the conversion coating or palladium coating, to be sufficient as a barrier layer against corrosion, but not “excessively” thick and potentially impede immersion metal deposition that follows, or adversely affect the wettability of the immersion metal coating and possibly impede solderability.

It is again noted, that the Pd layer to be used as a barrier in this invention, is differentiated from Pd activation layers widely used for catalyzing electroless nickel deposition, as follows:

1. Palladium catalysts of the prior art compositions are predominantly based on strongly acidic palladium chloride. In view of the corrosive action of chlorides, strongly acidic palladium chloride solutions are not best practice choices for forming optimal barriers of this invention. Instead, this patent favors mildly acidic ionic palladiun compositions that comprise anions such as phosphates, borates and the like, themselves known for their conversion, film-forming properties.

2. The Pd metal film of this invention has to be of sufficient thickness to act as a robust mechanical barrier or obstacle to corrosion. This, as opposed to Pd or Pd-bearing layers whose only action is to act as catalyst, often requiring no more than the presence of a trace amount of palladium on the surface of the substrate.

3. The Pd barrier film is preferably displacement-deposited from acidic palladium solutions comprising anions that can in themselves, act as conversion coatings, such as, for example, palladium solutions comprising anions of phosphate, sulfate, borate, or mixtures thereof, as mentioned earlier. Such anions seem to act synergistically with the deposited Pd, reinforcing the barrier effect.

When Pd is selected as the barrier film of choice, it is important not to exceed the minimum/optimum Pd film thickness indispensable for a functionally satisfactory barrier layer. This, in view of the high price of Pd metal, and also in order not to interfere with solderability.

Again, at the risk of being redundant, one skilled in the art will need to optimize the process by trial-and-error, as an excessively thick barrier layer may impede the formation of the top immersion coating, whereas if the barrier layer is too thin, it will not provide the desired barrier against corrosion.

In yet another preferred object and embodiment of instant invention, undesirable black nickel formation on pads of PWBs in service, is alleviated by formulating a highly corrosion resistant, electrolessly deposited nickel-copper-phosphorus alloy that will be less prone to black pad formation, when the final finish comprises electroless nickel followed by immersion gold. Compositions described in U.S. Pat. No. 4,482,596 to Gulla, can serve as an example of potential compositions that yield Ni/Cu/P deposits that offer improved protection against black nickel formation.

A further benefit of copper ions added to EN plating solutions, resides in their ability to provide bath stability without requiring use of stabilizers such as thio derivatives, nefarious lead, etc.

In this invention, all EN plating composition are based on hypophosphite reducers, that invariably result in nickel deposits alloyed with phosphorus. It is thus to be understood that EN coatings of this invention are always composed of nickel phosphorus alloy, as well known in the art.

In yet a further embodiment of this invention, the barrier layer can be co-deposited with immersion metal, for improved solderability. One envisions for example, a silver immersion composition comprising palladium salts such as, for example palladium nitrate, to yield immersion deposited Ag/Pd alloy.

It is further noted that the patent envisions optionally topping the immersion plated metal film with organic compositions as post-dips, if desired, as widely practiced by the prior art.

Summarizing, instant patent teaches immersion metal deposition, preceded by a barrier layer applied to copper substrate, minimizing via said barrier layer copper corrosion of PCBs in polluted environments.

While the patent discloses/proposes various methods and compositions to embody said barrier layer, a person skilled in the art may find alternative ways to achieve the desired barrier layer, for example by vacuum deposition. Such alternatives will be within the scope of this patent. The main limitation of this patent is deposition of the immersion metal film following an intermediate corrosion-barrier layer, and not directly over “clean” Cu as predicated by the prior art.

Finally, while the patent principally focuses on the benefits derived from conversion coatings prior to immersion metal deposition, its teachings are applicable to PCB finishes that also comprise electroless plating alone, or in combination with immersion deposited metal deposits.

Also, while instant patent primarily focuses on applying a conversion coating onto the copper metal substrate, prior to subsequent plating of a displacement metal layer such as Ag or Sn, it also contemplates, contacting with a conversion coating solution, the finished PWB, already coated with an immersion-plated metal layer such as Ag or Sn, thereby eliminating or at least substantially minimizing the potential presence of corrosion-causing exposed micropores reaching down to the copper metal substrate, by covering/capping said micropores with a conversion coating.

Above embodiment is preferably accomplished by adding a surfactant to the conversion bath, ensuring its penetration into the micropores or capillaries reaching down to copper metal.

### EXAMPLES

1. A through hole copper plated PWB panel was cleaned, microetched, water rinsed, then immersed at room temperature for about 5 minutes, with work agitation, in a dilute acidic ionic palladium solution comprising phosphoric acid, to form a silvery-looking Pd film. Following rinsing in water, the panel was contacted with a commercially available silver displacement composition, prepared and operated according to the supplier's recommendation.

The panel was rinsed, dried, then tested for creep corrosion (CC).

No CC was noted.

2. A PWB panel similar to the one used in Example 1, was coated with a silvery Pd film as in Example 1, then plated at 50 deg. C. in an ammoniacal hypohosphite-bearing EN composition adjusted to pH 8-9. The deposited nickel thickness was about 1 micron.

The panel was water rinsed, and immersion-plated with silver to a thickness of 0.25 micron, using a commercial silver immersion composition.

Following rinsing and drying, the panel tested negative for CC.

3. Same as Example 2, except that the commercially available electroless nickel plating composition was operated as recommended by the supplier, at a pH of about 4.5, and a temperature of about 80 deg. C. The EN deposit thickness was about 3 microns.

This was followed by plating immersion silver to a thickness of about 0.25 micron.

The sample tested negative to CC.

4. Same as Example 1, except that immersion silver was replaced with immersion tin.

After rinsing and drying and testing, there was no indication of the presence of undesirable whiskering or intermetallic Sn/Cu.

5. Same as Example 1, except that that the Pd barrier layer was followed by deposition of about 0.1 micron of elctroless copper plated in a formaldehyde-free, hyposphite-bearing electroless compositions as taught U.S. Pat. No. 4,265,943 and U.S. Pat. No. 6,524,490, then followed with immersion Ag.

CC corrosion tested negative.

6. Same as Example 3, except that the EN composition comprised copper sulfate, resulting in Ni/Cu alloy plate. It displayed a greater resistance to corrosion as compared to the EN composition in Example 2.

1. A method of reducing corrosion of through hole copper plated PWBs that are finished with an immersion coated metal, comprising deposition of a barrier layer onto the copper substrate and prior to subsequent immersion metal deposition, said barrier layer comprising a copper conversion coating.

2. A method of reducing corrosion of copper surfaces on printed circuit boards, said method comprising:
a) contacting said copper surface with a chemical conversion coating solution such that a conversion coating is formed on the copper surfaces;
b) contacting the conversion-coated copper surfaces with an electroless or immersion plating bath such that a plated metal is deposited on the conversion coated copper surface.

3. The method of claim 1, wherein the copper conversion coating is replaced with an immersion deposited Pd metal layer.

4. The method of claim 1, wherein the thickness of the barrier layer is at least 200 Angstroms.

5. The method of claim 2, wherein the thickness of the barrier layer is at least 200 Angstroms.

6. The method of claim 3, wherein the thickness of the barrier layer is at least 200 Angstroms.

7. The method of claim 1, wherein the barrier layer is followed by immersion plated Ag or Sn.

8. The method of claim 2, wherein the barrier layer is followed by immersion plated Ag or Sn.

9. The method of claim 3, wherein the barrier layer is followed by immersion plated Ag or Sn.

10. A method of reducing corrosion of copper through hole plated PWBs, comprising immersion depositing onto the copper substrate a Ag—Pd alloy as a final finish.

11. A method of reducing corrosion of copper plated through hole PWBs, wherein the barrier layer of claim 2 is followed by deposition of a Ni—P type EN, topped with immersion silver.

12. The method of claim 11, except that immersion silver is replaced with immersion gold.

13. The method of claim 11, wherein the Ni—P type EN deposit is an alloy of copper or silver.

14. The method of claim 12, wherein the Ni—P type EN deposit is an alloy of copper or silver.

15. A method of microetching and at the same time conversion coating a copper substrate of through hole plated PWBs, wherein the copper substrate is contacted with an acidic hydrogen peroxide composition comprising bezotriazole, imidazole, or a combination, said conversion layer is then followed by an immersion deposited coating of Ag or Sn.

16. The method of claim 15, except that said conversion layer is followed by immersion Pd layer, EN and immersion silver or immersion gold.
